(19) United States
(12) Patent Application Publication
(10) Pub. No.: US 2020/0194971 A1
(43) Pub. Date: Jun. 18, 2020

(54) Semiconductor Optical Integrated Device

(71) Applicant: Nippon Telegraph and Telephone Corporation, Chiyoda-ku, Tokyo (JP)

(72) Inventors: Takahiko Shindo, Atsugi-shi, Kanagawa-ken (JP); Wataru Kobayashi, Atsugi-shi, Kanagawa-ken (JP); Naoki Fujiwara, Atsugi-shi, Kanagawa-ken (JP); Shigeru Kanazawa, Atsugi-shi, Kanagawa-ken (JP)

(21) Appl. No.: 16/628,317

(22) PCT Filed: Sep. 12, 2018
(86) PCT No.: PCT/JP2018/033845

§ 371 Date: Jan. 3, 2020

(30) Foreign Application Priority Data
Sep. 19, 2017 (JP) 2017-179535

(51) Int. Cl. H01S 5/0683; H01S 5/068; H01S 5/12; H01S 5/026

(52) U.S. Cl. CPC H01S 5/0683; H01S 5/0264; H01S 5/12; H01S 5/06821

(57) ABSTRACT

There is provided a semiconductor optical integrated device having a DFB laser, an EA modulator, and an SOA monolithically integrated, and an output light intensity of the semiconductor optical integrated device is maintained constant. The semiconductor optical integrated device includes: a DFB laser; an EA modulator connected to the DFB laser; an SOA monolithically integrated with the DFB laser and the EA modulator on a same substrate and connected to an output end of the EA modulator; and an optical receiver disposed on an output end side of the SOA and having a same composition as the SOA. The optical receiver is configured to monitor change in a detection value according to an intensity of input light to the optical receiver such that drive currents flowing in the DFB laser and the SOA are feedback controlled.

### TECHNICAL FIELD

The present invention relates to a DFB (distributed feedback) semiconductor optical integrated device, and more particularly to a semiconductor optical integrated device for monitoring a light intensity.

### BACKGROUND ART

A DFB (distributed feedback) laser has excellent single wavelength characteristics, and there is known an aspect that the DFB laser is monolithically integrated with an EA (electroabsorption) modulator on a single substrate. The semiconductor optical integrated device having such an aspect (an EA-DFB laser) is used as an optical transmitter for long-distance transmission, i.e., a transmission distance of 40 km or longer. As an optical wavelength of signal light, the EA-DFB laser mainly uses the 1.55 μm-band, in which an optical fiber has a low propagation loss, or the 1.3 μm-band, in which an optical fiber is less likely to be affected by wavelength dispersion.

Generally, it is preferable that an EA-DFB laser for optical fiber transmission maintains the light intensity of an optical signal constant. Thus, the light intensity of output light from the EA-DFB laser has been monitored, and the current flowing in the DFB laser has been controlled to maintain the monitored light intensity constant. This is referred to as APC (auto power control).

Traditionally, on the assumption of a multiplexed optical transmitter module having a DFB laser and an EA modulator, there is disclosed a configuration of monitoring the light intensity of the DFB laser for APC, in which an optical receiver is provided on a face opposite to an output end of the DFB laser (see, for example, FIG. 6 in PTL 1).

Traditionally, the optical receiver provided on the face opposite to the output end of the DFB laser is configured to monitor the light intensity. However, some optical transmitters achieve long-distance transmission with not only the EA-DFB laser (the DFB laser and the EA modulator), but also an SOA (a semiconductor optical amplifier), which are monolithically integrated on the same substrate (see, for example, PTL 2). In this configuration, as will be described below, even if the light intensity is monitored at a position of the optical receiver, which the traditional configuration assumes, that is, on the face opposite to the output end of the DFB laser, feedback control which maintains the light intensity constant cannot be performed.

The optical receiver, which the traditional configuration assumes, is provided on the face opposite to the output end of the DFB laser and monitors only the light intensity of the DFB laser. For this reason, even if an amplification factor of the SOA decreases due to deterioration of the SOA, it is impossible to detect change in the light intensity. Since decrease in an amplification factor of the SOA cannot be detected, feedback control will not be carried out, resulting in decrease in the light intensity of the DFB laser.

### CITATION LIST

### Patent Literature

PTL 1: Japanese Patent Laid-Open No. 2016-180779

PTL 2: Japanese Patent No. 5823920

### SUMMARY OF INVENTION

An object of the present invention is to provide a semiconductor optical integrated device as an optical transmitter having a DFB laser, an EA modulator, and an SOA monolithically integrated, wherein feedback control which maintains the light intensity of the DFB laser constant can be performed.

To achieve the above object, a semiconductor optical integrated device of the present invention includes: a DFB laser; an EA modulator connected to the DFB laser; an SOA monolithically integrated with the DFB laser and the EA modulator on a same substrate and connected to an output end of the EA modulator; and an optical receiver disposed on an output end side of the SOA and having a same composition as the SOA, wherein a forward bias voltage or a forward bias current is applied to the optical receiver, and the optical receiver is configured to monitor change in a detection value according to an intensity of input light to the optical receiver such that drive currents flowing in the DFB laser and the SOA are feedback controlled.

Incidentally, each of the DFB laser and the SOA may be connected to the same control terminal, and the same control terminal may be configured such that the drive current flows in each of the DFB laser and the SOA.

### BRIEF DESCRIPTION OF DRAWINGS

FIG. 1 is a diagram for schematically explaining control of a semiconductor optical integrated device according to an embodiment of the present invention,

FIG. 2 is a graph for explaining the relationship among Iₒₚ, I_{DFB}, and I_{SOA} in the semiconductor optical integrated device of the embodiment,

FIG. 3 is a diagram showing a configuration example of the semiconductor optical integrated device of the embodiment,

FIG. 4A is a diagram for explaining a method for monitoring a voltage driven optical receiver, and

FIG. 4B is a diagram for explaining a method for monitoring a current driven optical receiver.

### DESCRIPTION OF EMBODIMENTS

Now, a semiconductor optical integrated device (hereinafter referred to simply as an “optical integrated device”) of an embodiment of the present invention will be described. In the optical integrated device of this embodiment, an EA-DFB laser and an SOA are integrated.

### Summary of Control of Optical Integrated Device 100

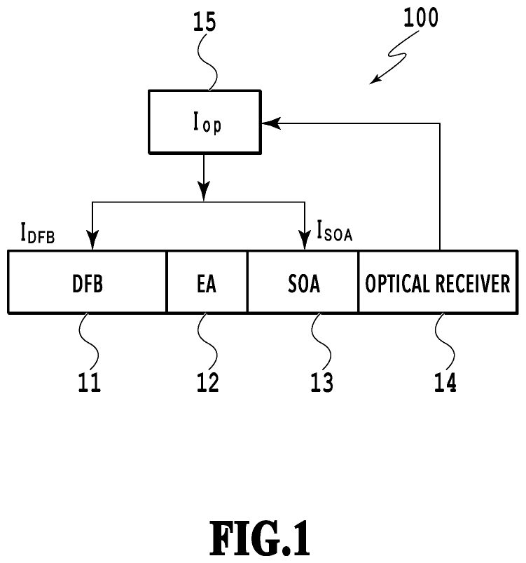

FIG. 1 is a diagram for schematically explaining control of an optical integrated device 100 according to the present embodiment. The optical integrated device 100 has a DFB laser 11, an EA modulator 12, and an SOA 13 in this order in an optical waveguide direction. These components 11 to 13 are monolithically integrated and laminated on a single semiconductor substrate. The optical integrated device 100 further has an optical receiver 14 for monitoring, which is disposed on an output end side of the SOA 13.

In FIG. 1, the DFB laser 11 and the SOA 13 are controlled according to a current value Iₒₚ flowing from the same control terminal 15. At this time, if a current flowing in the DFB laser 11 is indicated by I_{DFB} and a current flowing in the SOA 13 is indicated by I_{SOA}, the current value Iₒₚ is represented by Iₒₚ=I_{DFB}+I_{SOA}. In general, an acceptable value of Iₒₚ in an optical transmission module having the EA-DFB laser installed thereon is in the range of 60 to 80 mA. In this respect, it is preferable that an upper limit of Iₒₚ in the optical integrated device 100 of the present embodiment is set to 80 mA, for example.

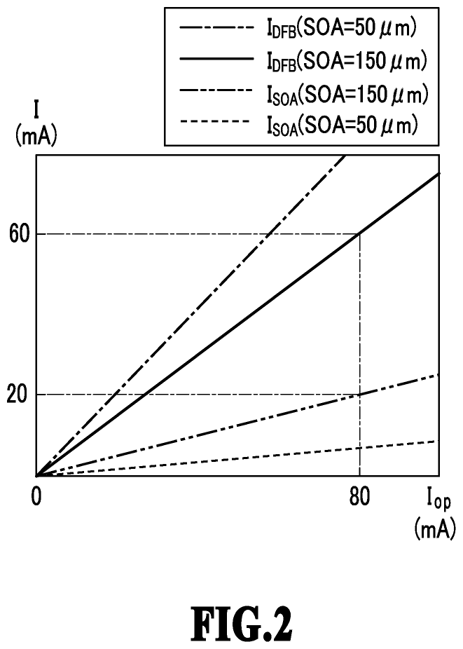

The relationship among the above-mentioned I_{OP}, I_{DFB}, and I_{SOA} will be described with reference to FIG. 2. The horizontal axis indicates a current value of Iₒₚ, and the vertical axis indicates a current value of I_{DFB} and I_{SOA}. In FIG. 2, the DFB laser 11 having a length of 450 μm in an optical waveguide direction is used. As shown in FIG. 2, if the SOA 13 has a length of 50 μm, for example, the length of the SOA is one-ninth the length of the DFB laser 11 (450 μm), and thus the current value Iₒₚ mostly flows in the DFB laser 11. Meanwhile, if the SOA has a length of 150 μm, the length of the SOA is one-third the length of the DFB laser, and thus, if Iₒₚ=80 mA, I_{DFB} of about 60 mA flows in the DFB laser and I_{SOA} of about 20 mA flows in the SOA.

As described above, by adjusting the lengths of the DFB laser 11 and the SOA 13, it is possible to adjust the currents I_{DFB}, I_{SOA} flowing therein. More specifically, if the DFB laser 11 has a length of 450 μm, to obtain a threshold current and an SMSR (sub-mode suppression ratio) in driving the DFB laser 11, Iₒₚ needs to be at least 60 mA. Therefore, it is preferable that the SOA has a length of 150 μm or smaller in an optical waveguide direction. Furthermore, if the length of the DFB laser 11 is set to 300 μm, to obtain a necessary SMSR, Iₒₚ may be set to a value as small as about 40 mA. Accordingly, it is also possible to make the SOA 13 longer and increase the current I_{SOA} flowing in the SOA 13. By changing the length of the SOA 13 according to a balance (ratio) between the length of the DFB laser 11 and the length of the SOA 13 so that a minimum current can be applied to the DFB laser 11 having a predetermined length, it is possible to realize both stable single mode operation and amplification of light output.

### [Configuration of Optical Integrated Device 100]

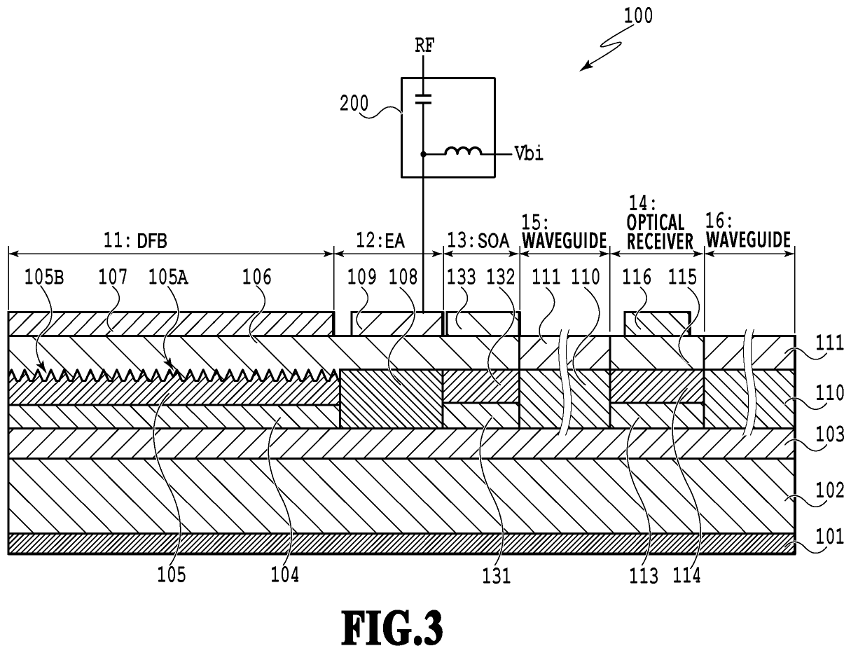

Next, the configuration of the above-described optical integrated device 100 will be described with reference to FIG. 3. It should be noted that materials described in connection with the description of the configuration of the optical integrated device 100 are given as examples, and may be freely modified.

FIG. 3 is a diagram showing a configuration example of the optical integrated device 100. The optical integrated device 100 has an n-type InP substrate 102, on which the DFB laser 11, the EA modulator 12, the SOA 13, and the optical receiver 14 are formed in this order in an optical waveguide direction. On a back side of the substrate 102, an n-type electrode 101 is provided. On an input side of the optical receiver 14, for example, a waveguide 15 connected to the SOA 13 is formed, and on an output side of the optical receiver 14, a waveguide 16 is formed. It should be noted that unlike the configuration shown in FIG. 3, instead of forming a waveguide 15, the SOA 13 and the optical receiver 14 may be electrically separated from each other by a contact layer (not shown) formed by etching. Furthermore, a waveguide 16 may not need to be formed on the output side of the optical receiver 14.

The DFB laser 11 has an active layer 104 and a guide layer 105 laminated on an n-InP cladding layer 103. The guide layer 105 includes a λ/4 phase shift 105A and a grading 105B. The active layer 104 is formed of InGaAlAs based or InGaAsP based material. A p-InP cladding layer 106 is formed on the guide layer 105, and a p-type electrode 107 is provided on the cladding layer 106. The current I_{DFB} shown in FIG. 1 flows in the electrode 107.

The EA modulator 12 has an absorption layer 108, the cladding layer 106, and a p-type electrode 109 laminated on the cladding layer 103. Across the electrode 109, a bias voltage V_{bi} and a high-frequency voltage RF for driving the EA modulator 12 are applied through a bias T200. This allows the EA modulator 12 to modulate light from the DFB laser 11. The absorption layer 108 is formed of InGaAlAs based or InGaAsP based material, and has a quantum well structure.

The SOA 13 has an active layer 131, a guide layer 132, the cladding layer 106, and a p-type electrode 133 laminated on the cladding layer 103. The active layer 131 has the same composition as the active layer 104 of the DFB laser 11, and the guide layer 132 has the same composition as the guide layer 105 of the DFB laser 11. In this embodiment, the current I_{SOA} shown in FIG. 1 flows in the electrode 133 of the SOA 13. In this embodiment, the DFB laser 11 and the SOA 13 have an emission wavelength of about 1.55 μm at a temperature of 25° C., for example.

The optical receiver 14 has a light receiving layer 113, a guide layer 114, an upper cladding layer 115, and a p-type electrode 116 laminated on the cladding layer 103. Across the electrode 116, a voltage equal to or greater than a built-in voltage Vb, which will be described later, or a current equal to or greater than a transparency current Iₜₚ of the SOA 13 is applied. The optical receiver 14 of this embodiment has a waveguide having the same composition as the SOA 13. In other words, the light receiving layer 113 of the optical receiver 14 has the same composition as the active layer 131 of the SOA 13, and the guide layer 114 has the same composition as the guide layer 132 of the SOA 13. Furthermore, the upper cladding layer 115 of the optical receiver 14 has the same composition as the cladding layer 106 of the SOA 13. Both the SOA 13 and the optical receiver 14 have the cladding layer 103.

Each of the waveguides 15, 16 has a core layer 110 and a non-doped InP layer 111. The core layers 110 in the waveguides 15, 16 have the same composition as the light receiving layer 113 of the optical receiver 14.

### Method for Monitoring Optical Receiver 14

Now, a method for monitoring the optical receiver 14 of the above-described optical integrated device 100 will be described. A forward bias voltage or bias current is applied to the optical receiver 14, and a voltage value or a current value according to the intensity of input light to the optical receiver 14 is monitored. In the optical integrated device 100 of the present embodiment, according to the change in the voltage value (current value), the monitoring result is fed back to the current value I, and the intensity of output light from the optical receiver 14 (output light from the optical integrated device 100) is adjusted to be constant.

It is generally known that an amplification factor decreases as an SOA aged deterioration. In the optical integrated device 100 of the present embodiment, an amplification factor decreases as the SOA 13 aged deterioration, and the optical receiver 14 is formed of the same composition as the SOA 13. This is to monitor change in an amplification factor that decreases as the optical receiver 14 aged deterioration like the SOA 13. In other words, not only the output light from the DFB laser 11, but also a secular change in the SOA 13 is monitored.

In a case where a forward bias is applied to the optical receiver 14 to drive the optical receiver 14, a secular change in the optical receiver 14 itself needs to be considered. To allow the optical receiver 14 to maintain the function of monitoring the light intensities of the DFB laser 11 and the SOA 13, there is need of operation conditions in which a deterioration speed is lower and the secular change is smaller as compared to those of the DFB laser 11 and the SOA 13. Generally, in an optical device driven by the application of a forward bias, a deterioration speed is accelerated depending on a carrier concentration at the time of operation. Therefore, it is preferable that a carrier concentration of the optical receiver 14 is smaller than those of the SOA 13 and the DFB laser 11. However, the carrier concentration of the DFB laser is clamped by a threshold carrier concentration and is substantially a constant value irrespective of a drive current. On the other hand, since a carrier concentration increases depending on a drive current in the SOA, the carrier concentration of the SOA is generally higher than the carrier concentration of the DFB laser. Therefore, by taking only the carrier concentration of the SOA 13 into consideration, operation conditions of the optical receiver 14 may be determined.

In view of this, in a case where the optical receiver 14 is voltage driven for monitoring change in current with a constant voltage applied, a voltage greater than a built-in voltage V_{b} is applied as a forward bias voltage across the optical receiver 14. This is different from a reverse bias voltage (−3V) applied across a typical optical receiver for monitoring, provided on a face opposite to an output end of the DFB laser. This is because a voltage needs to have a value that applies a transparency carrier concentration current in order to detect deterioration over time of the optical receiver 14, namely, the SOA 13. In addition, in a case where the optical receiver 14 is voltage driven, with respect to a drive voltage V_{SOA} of the SOA 13, a forward bias voltage Vₘₒₙᵢₜₒᵣ applied across the optical receiver 14 needs to satisfy Vₘₒₙᵢₜₒᵣ<V_{SOA}.

In a case where the optical receiver 14 is current driven for monitoring change in voltage with a constant current applied, a forward bias current may flow in the optical receiver 14. In this case as well, a current equal to or greater than a transparency current Iₜₚ of the SOA 13 is applied to the optical receiver 14 in order to detect deterioration over time of the optical receiver 14, namely, the SOA 13. In addition, in a case where the optical receiver 14 is current driven and the SOA 13 and the optical receiver 14 have the same waveguide width W, carrier concentrations are respectively proportional to a length L_{SOA} in a light axis direction of the SOA 13 and a length Lₘₒₙᵢₜₒᵣ in a light axis direction of the optical receiver 14. Therefore, with respect to a drive current I_{SOA} of the SOA 13, a forward bias current Iₘₒₙᵢₜₒᵣ applied to the optical receiver 14 needs to satisfy Iₘₒₙᵢₜₒᵣ/Lₘₒₙᵢₜₒᵣ<I_{SOA}/L_{SOA}.

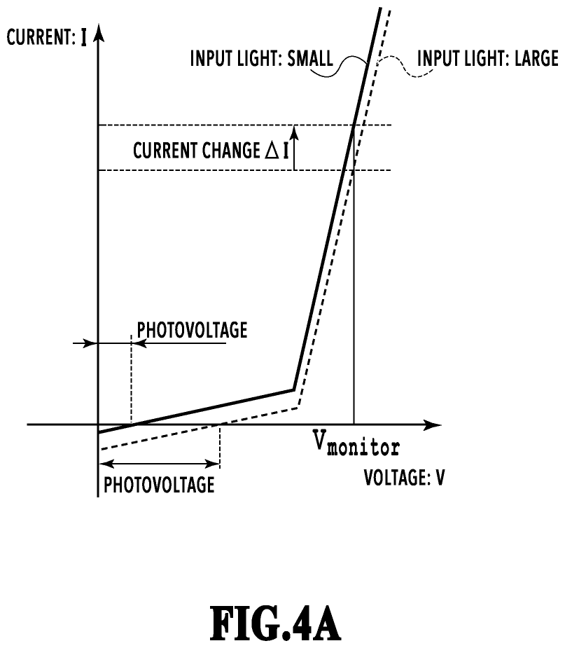

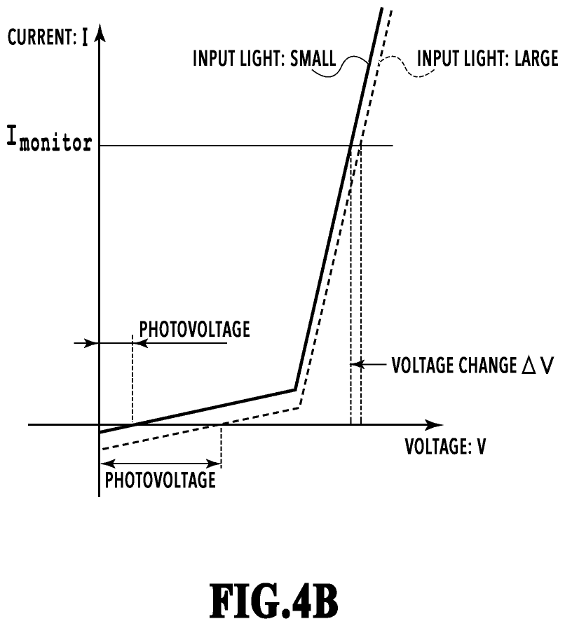

FIG. 4A is a diagram for explaining a method for monitoring a voltage driven optical receiver. A description will be given of a control method in a case where the intensity of light entering the optical receiver 14 has changed. If light enters the optical receiver 14, a forward photovoltage is generated by light absorption. Meanwhile, in a case where the intensity of light entering the optical receiver 14 decreases due to the deterioration of the SOA 13 and the like, a photovoltage becomes small. At this time, if the optical receiver 14 is voltage driven, that is, while Vₘₒₙᵢₜₒᵣ is constant, a current applied to the optical receiver 14 increases to maintain the drive voltage Vₘₒₙᵢₜₒᵣ of the optical receiver 14 (ΔI in FIG. 4A). Accordingly, the current value Iₒₚ is feedback controlled according to the increase in the current so that the intensity of light output from the optical integrated device 100 is adjusted to be constant.

FIG. 4B is a diagram for explaining a method for monitoring a current driven optical receiver. If the optical receiver 14 is current driven, that is, while Iₘₒₙᵢₜₒᵣ is constant, in a case where the light intensity decreases as the SOA 13 aged deterioration, a voltage applied across the optical receiver 14 decreases to maintain the drive current Iₘₒₙᵢₜₒᵣ of the optical receiver 14 (ΔV in FIG. 4B). Accordingly, the current value Iₒₚ is feedback controlled according to the decrease in the voltage so that the intensity of light output from the optical integrated device 100 is adjusted to be constant.

In this manner, a forward bias voltage or a forward bias current is applied to the optical receiver 14, and a current value or a voltage value according to the intensity of light entering the optical receiver 14 is monitored. Accordingly, the current value Iₒₚ is fed back according to the monitoring result so that the intensity of the output light from the optical integrated device 100 is adjusted to be constant.

As described above, in the optical integrated device 100 of the present embodiment, the DFB laser 11, the EA modulator 12, and the SOA 13 are monolithically integrated on the same substrate, and the optical receiver 14 having the same composition as the SOA 13 is disposed on the output end side of the SOA 13. A forward bias (a voltage equal to or greater than a built-in voltage V_{b} or a current equal to or greater than a transparency current Iₜₚ) is applied to the optical receiver 14, and the optical receiver 14 is configured to monitor change in a detection value (a voltage value or a current value) according to the input light intensity.

According to this configuration, even if an amplification factor of the SOA 13 decreases, a detection value monitored by the optical receiver 14 changes, and it is possible to feedback control the current value Iₒₚ supplied from the same terminal 15 according to the change. This allows adjustment of the values I_{DFB} and I_{SOA}, and the intensity of output light from the optical integrated device 100 can be maintained constant.

### MODIFICATION EXAMPLE 1

Next, a modification example of the optical integrated device 100 of the present embodiment will be described. In the above-described embodiment, an aspect of installing the optical integrated device 100 in an optical transmission module has not been mentioned. However, the optical transmission module may have the optical integrated device 100.

### MODIFICATION EXAMPLE 2

In the above-described embodiment, with reference to FIG. 1, a description has been given of the case where a current flows in each of the DFB laser 11 and the SOA 13 from the same control terminal 15. However, a current may flow in each of the DFB laser 11 and the SOA 13 from different control terminals. In this case, a current I_{DFB} and a current I_{SOA} flow in the p-type electrodes 107, 133 of the DFB laser and the SOA from their respective control terminals.

### MODIFICATION EXAMPLE 3

In the above-described embodiment, a description has been given of the case where oscillation occurs at a wavelength of 1.55 μm, but the same effect as the above-described embodiment can be obtained by applying a wavelength other than 1.55 μm. For instance, also in a case where oscillation occurs at a wavelength in the 1.3 μm-band, crystal compositions of the components 11, 12, 13 of the optical integrated device 100 for optical communication may be changed and applied.

1.-4. (canceled)

5. A semiconductor optical integrated device comprising:
a DFB laser;
an EA modulator connected to the DFB laser;
an SOA monolithically integrated with the DFB laser and the EA modulator on a same substrate and connected to an output end of the EA modulator; and
an optical receiver disposed on an output end side of the SOA and having a same composition as the SOA,
wherein a forward bias voltage or a forward bias current is applied to the optical receiver, and the optical receiver is configured to monitor change in a detection value according to an intensity of input light to the optical receiver such that drive currents flowing in the DFB laser and the SOA are feedback controlled.

6. The semiconductor optical integrated device according to claim 5, wherein each of the DFB laser and the SOA is connected to a same control terminal, and the same control terminal is configured such that the drive current flows in each of the DFB laser and the SOA.

7. The semiconductor optical integrated device according to claim 5, wherein the forward bias voltage Vₘₒₙᵢₜₒᵣ satisfies V_{b}<Vₘₒₙᵢₜₒᵣ<V_{SOA}, where a built-in voltage of the optical receiver is indicated by V_{b} and a drive voltage of the SOA is indicated by V_{SOA}.

8. The semiconductor optical integrated device according to claim 6, wherein the forward bias voltage Vₘₒₙᵢₜₒᵣ satisfies V_{b}<Vₘₒₙᵢₜₒᵣ<V_{SOA}, where a built-in voltage of the optical receiver is indicated by V_{b} and a drive voltage of the SOA is indicated by V_{SOA}.

9. The semiconductor optical integrated device according to claim 5, wherein the forward bias current Iₘₒₙᵢₜₒᵣ is a current equal to or greater than a transparency current value of the SOA, and
the forward bias current Iₘₒₙᵢₜₒᵣ satisfies Iₘₒₙᵢₜₒᵣ/Lₘₒₙᵢₜₒᵣ<I_{SOA}/L_{SOA}, where a drive current of the SOA is indicated by I_{SOA}, a length of the optical receiver in a light axis direction is indicated by Lₘₒₙᵢₜₒᵣ, and a length of the SOA in a light axis direction is indicated by L_{SOA}.

10. The semiconductor optical integrated device according to claim 6, wherein the forward bias current Iₘₒₙᵢₜₒᵣ is a current equal to or greater than a transparency current value of the SOA, and
the forward bias current Iₘₒₙᵢₜₒᵣ satisfies Iₘₒₙᵢₜₒᵣ/Lₘₒₙᵢₜₒᵣ<I_{SOA}/L_{SOA}, where a drive current of the SOA is indicated by I_{SOA}, a length of the optical receiver in a light axis direction is indicated by Lₘₒₙᵢₜₒᵣ, and a length of the SOA in a light axis direction is indicated by L_{SOA}.
